(19) United States
(12) Patent Application Publication
(10) Pub. No.: US 2012/0018703 A1
(43) Pub. Date: Jan. 26, 2012

(54) OPTOELECTRONIC SEMICONDUCTOR COMPONENT AND METHOD FOR THE MANUFACTURE THEREOF

(76) Inventors: Klaus Köhler, Freiburg (DE); Christian Manz, Freiburg (DE)

(21) Appl. No.: 13/139,763

(22) PCT Filed: Dec. 18, 2009
(86) PCT No.: PCT/EP09/67467

§ 371 Date: Jun. 15, 2011

(30) Foreign Application Priority Data
Dec. 20, 2008 (DE) 10 2008 064 316.5

(51) Int. Cl. H01L 29/12; H01L 21/66; H01L 21/20

(52) U.S. Cl. 257/14; 438/478; 438/14; 257/435; 257/E21.119; 257/E29.069; 257/E21.53

(57) ABSTRACT

Manufacturing semiconductor heterostructures by way of molecular beam epitaxy, including placing a substrate into a first vacuum chamber, heating the substrate to a first temperature, depositing from at least one molecular beam a first epitaxial layer of a first material containing a binary, ternary or quaternary compound of elements of main group III and V, cooling the substrate to a second temperature, interrupting the molecular beam by elements of main group III and V, heating the substrate to a third temperature and depositing from at least one molecular beam a second epitaxial layer of a second material containing a binary, ternary, or quaternary compound of elements of main group III and V and that is deposited from at least one molecular beam; and semiconductor components produced thereby.

### BACKGROUND

The invention relates to a method for manufacturing semiconductor heterostructures by means of molecular beam epitaxy, comprising the following steps: introducing a substrate into a first vacuum chamber, heating the substrate to a first temperature, producing the first epitaxial layer, wherein the layer contains a first material containing a binary, ternary or quaternary compound of elements of main group III and V, and producing the second epitaxial layer, wherein the layer contains a second material composed of a binary, ternary or quaternary compound of elements of main group III and V.

Klaus Ploog: Mikroskopische Strukturierung von Festkörpern durch Molekularstrahl-Epitaxie [Microscopic structuring of solids by molecular beam epitaxy], Angew. Chem. 100 (1988), pages 611-639, discloses manufacturing semiconductor components made from a plurality of different materials having different lattice constants and/or different band gap energies. At the interface between both materials, a step arises in the energy level of the valence and/or conduction band. As a result, the electrical transport can be interrupted perpendicularly to the layer boundaries, but maintained further within the individual layer. By depositing a plurality of semiconductor layers having different band gap energies one above another, it is possible to produce dimensional quantum effects within the layers. This means that the wave vector of the charge carriers is quantized in a direction perpendicular to the layer course.

Since the position of the discrete energy levels established changes with the layer thickness, not only the electrical but also the optical properties are influenced. Therefore, it is possible to use semiconductor heterostructures for manufacturing transistors with high electron mobility, semiconductor lasers, luminescence diodes, photodiodes and quantum cascade detectors.

An epitaxial growth method can be employed for manufacturing the heterostructures. This means that the constituent elements of a semiconductor layer are directed as a molecular beam onto a substrate surface, where they synthesize to form the corresponding layer material. In this case, the crystal structure of the growing layer can be influenced by the crystal structure of the underlying layer or of the substrate, such that the layer grows in a manner largely free of crystal defects. In order to produce heterostructures, i.e. layers having different chemical compositions and, resulting therefrom, different lattice constants and band gap energies, the intensity of individual molecular beams is altered during growth at predeterminable time intervals. This can be done, for example, by increasing or reducing the energy fed to an evaporation source. Furthermore, it is known, by means of movable diaphragms, to at least partly close off the exit opening of a source in order, in this way, to influence the intensity of the emerging molecular beam.

While relatively small adaptations of the layer composition can normally be obtained by means of movable diaphragms, larger interventions in the composition of the molecular beam require adaptation of the temperature of at least one evaporation source and/or the measurement of the flow emerging from the evaporation source. Further growth of semiconductor layers on the substrate is not possible during this period of time. There is simultaneously the risk of individual components outgassing from the semiconductor layers deposited on the substrate up to this point in time. Said components can be antimony, arsenic or phosphorus. This outgassing has the effect that the stoichiometric composition of the layers is altered and the layers change their electronic and/or optical properties on account of the metal excess established.

In order to solve this problem, it is known from C. T. Foxon and B. A. Joyce: Interaction kinetics of As₄ and Ga on {100} GaAs surfaces using a modulated molecular beam technique, Surface Science 50 (1975), pages 434-450, during an interruption of growth, to maintain a continuous flow of elements of the fifth main group in the direction of the growing semiconductor layer structure, in order to compensate for the loss of material of the layer structure. The flow of elements of the fifth main group can contain antimony and/or arsenic and/or phosphorus.

What is disadvantageous about this procedure, however, is that the molecular beam impinging during the interruption of growth also introduces impurities which can form an undesirable interlayer at the interface between two semiconductor layers having different compositions.

Consequently, the object of the present invention is to prevent a contamination of a semiconductor surface during an interruption of growth.

### SUMMARY

The object is achieved according to the invention by means of a method for manufacturing semiconductor heterostructures by means of molecular beam epitaxy, comprising the following steps: introducing a substrate into a first vacuum chamber, heating the substrate to a first temperature, producing a first epitaxial layer, wherein the layer contains a first material which contains a binary, ternary or quaternary compound of elements of main group III and V and is deposited from at least one molecular beam, cooling the substrate to a second temperature, wherein the molecular beam of elements of main group III and V is interrupted, heating the substrate to a third temperature, and producing a second epitaxial layer, wherein the second layer contains a second material which contains a binary, ternary or quaternary compound of elements of main group III and V and is deposited from at least one molecular beam.

Furthermore, the object is achieved by means of an optoelectronic semiconductor component containing a plurality of layers, wherein at least two layers are obtainable by a substrate being introduced into a vacuum chamber, the substrate being brought to a first temperature, the first epitaxial layer being produced, wherein the layer contains a first material containing a binary, ternary or quaternary compound of elements of main group III and V, the substrate being brought to a second temperature, which is lower than the first temperature, wherein the at least one molecular beam of elements of main group III and V is interrupted, the substrate being brought to a third temperature, and the second epitaxial layer being produced, wherein the second layer contains a second material containing a binary, ternary or quaternary compound of elements of main group III and V.

In the following description of the invention, the term substrate is used not only for the carrier material initially used, but also for a carrier material onto which one or a plurality of layers of a semiconductor material have already been deposited. Such layers can be electronically active layers or buffer layers which can reduce a lattice mismatch between the lattice constant of the carrier material initially used and the layer deposited thereon. In this case, a binary, ternary or quaternary compound of elements of the third and fifth main groups can be used as semiconductor material. The surface of the substrate can accordingly also be that surface of the last deposited semiconductor layer which is exposed to the surroundings.

The known methods for manufacturing semiconductor heterostructures are based on the fact that the epitaxial growth of monocrystalline semiconductor layers made from molecular beams requires an elevated temperature, which lies between 400° C. and 700° C., for example. However, said elevated temperature has the effect that constituents of the semiconductor heterostructure already produced evaporate, i.e. are converted back into the gaseous state, when the corresponding molecular beam is interrupted. This can concern elements of the fifth main group, such as, for example, antimony, arsenic or phosphorus.

According to the invention, it has now been recognized that the known methods incorrectly assume that it is not possible to cool the semiconductor heterostructure during an interruption of growth since, in this way, impurities from the residual gas surrounding the semiconductor heterostructure are bound to the surface of the layer deposited last and thereby contaminate the latter to an even greater extent. According to the invention, however, it has now been recognized that interfaces with reduced impurities can be manufactured by the substrate with the semiconductor layers situated thereon being cooled to a temperature at which the vapor pressure of the constituents is low enough to prevent conversion into the gas phase in an appreciable amount. As a result, the stabilizing molecular beam can simultaneously be switched off, such that no impurities are transported with the molecular beam onto the surface of the semiconductor layer deposited last.

In some embodiments of the invention in accordance with the method now proposed, the known As-drag effect can be prevented or at least reduced. Said effect arises by virtue of the fact that impurities, such as indium emerging unintentionally from an evaporation source, are transported with another molecular beam, such as an arsenic beam and/or an antimony beam, onto the surface of the substrate. Since the invention now proposes also interrupting the arsenic beam during an interruption of growth, this contamination is avoided. However, interrupting the arsenic beam requires a temperature reduction in order to prevent arsenic from evaporating from the semiconductor heterostructure. In this case, in a totally surprising manner, it has been found that this temperature reduction does not have the effect that impurities from the residual gas are attached to the surface of the semiconductor heterostructure to an increased extent.

In one embodiment of the invention, all the molecular beams can be interrupted by the substrate being transferred into a second vacuum chamber. For this purpose, bellows-sealed manipulators and/or magnetically coupled transfer rods can be used in a manner known per se. The second vacuum chamber can then be separated from the first vacuum chamber, in which the semiconductor layers are deposited from a molecular beam on the substrate, by means of a slide effecting a tight-fitting seal. In this case, the second vacuum chamber can be a vacuum chamber designed in a dedicated manner for storing substrates, or else a vacuum chamber in which other coating or measurement methods can be carried out on the substrate.

In some embodiments of the invention, the residual gas pressure in said second vacuum chamber is less than 5·10⁻⁹ mbar. In some embodiments of the invention, the residual gas pressure in said second vacuum chamber is less than 5·10⁻¹⁰ mbar. In some embodiments of the invention, the partial pressure of nitrogen and/or oxygen and/or water vapor is even lower, for example less than 1·10⁻¹¹ mbar.

In a further embodiment of the invention, the molecular beam can be interrupted by a diaphragm being arranged between the substrate and the source of the molecular beam. The complicated and fault-susceptible transfer of the substrate into a second vacuum chamber can be prevented in this way. A shorter interruption of growth is possible as a result.

The method proposed according to the invention can be used for manufacturing optoelectronic semiconductor components, for example photodetectors and/or semiconductor lasers. Such known optoelectronic semiconductor components can contain, for example, approximately 50 to approximately 300 individual layers and have a total thickness of approximately 1 μm to approximately 9 μm. In this case, each individual layer contains a binary, ternary or quaternary compound of elements of the third or fifth main group, such as aluminum, indium, gallium, antimony, arsenic and/or phosphorus. In this case, it is familiar to the person skilled in the art, of course, that impurities can furthermore be present to a small extent in the semiconductor layers or at the interfaces thereof. Said impurities can comprise carbon, hydrogen, oxygen and/or nitrogen. However, they amount to less than one atomic layer, that is to say undesirable interlayers are not formed.

The method proposed according to the invention can also be used for manufacturing semiconductor components having a larger number of individual layers and/or a larger thickness, since the interruption of growth as proposed according to the invention can also last longer, for example overnight. As a result, it is possible to produce more individual layers than previously possible on a single working day. As a result, it is also possible to manufacture optoelectronic semiconductor components having approximately 300 to approximately 1000 individual layers and a total thickness of approximately 9 μm to approximately 30 μm.

### BRIEF DESCRIPTION OF THE DRAWINGS

The invention will be explained in greater detail below with reference to figures and an exemplary embodiment without restricting the general concept of the invention. In this case:

FIG. 1 shows an exemplary embodiment of an apparatus that can be used to carry out the method proposed.

FIG. 2 shows a manufacturing method for a known semiconductor laser.

FIG. 3 shows a manufacturing method according to the invention for a semiconductor laser.

FIG. 4 shows a depth-resolved element analysis of a semiconductor laser manufactured in accordance with the known method.

FIG. 5 shows a depth-result element analysis of a semiconductor laser manufactured in accordance with the method according to the invention.

FIG. 6 shows X-ray structure analyses of a known semiconductor laser and of a semiconductor laser according to the present invention and also a theoretical calculation in comparison.

FIG. 7 shows the efficiency of a semiconductor laser according to the invention in comparison with a known semiconductor laser.

### DESCRIPTION OF PREFERRED EMBODIMENTS

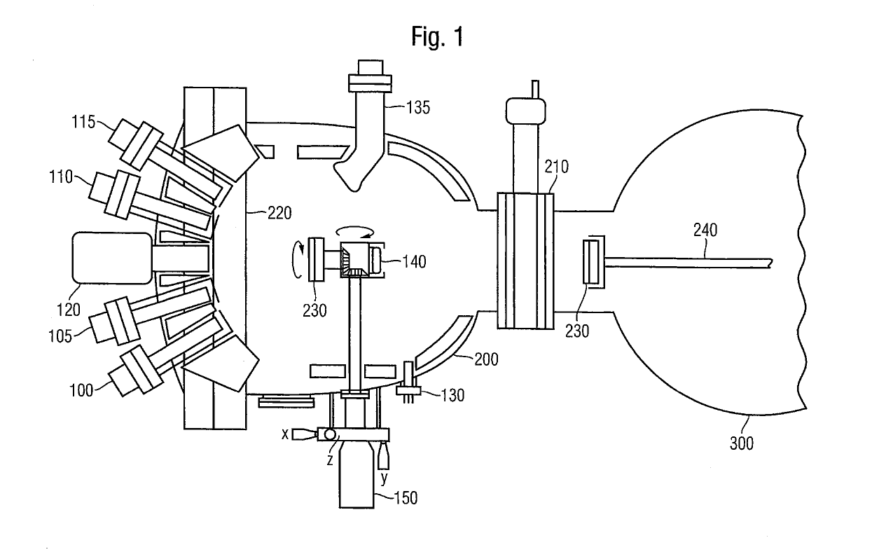

FIG. 1 shows a first vacuum chamber 200, into which a substrate 230 can be introduced. The substrate 230 can be arranged on a manipulator 150, which allows rotation and/or transverse displacement in one or a plurality of spatial directions. Examples of a suitable substrate 230 include sapphire or GaSb, onto the surface of which at least two, but preferably approximately 50 to approximately 300, semiconductor layers having a total thickness of approximately 3 μm to approximately 11 μm are deposited. After the completion of the semiconductor heterostructure, the GaSb substrate can be removed or else singulated together with the semiconductor heterostructure to form components.

The vacuum chamber 200 is evacuated by means of one or more vacuum pumps (not illustrated). By way of example, turbo molecular pumps, ion getter pumps, titanium sublimation pumps, cryopumps or further vacuum pumps known per se are suitable for this purpose. The background pressure in the vacuum chamber 200 can be less than 5·10⁻⁹ mbar, and in some embodiments of the invention also less than 5·10⁻¹⁰ mbar. An ionization manometer 130 is available for measuring the background pressure. Optionally, a quadrupole mass spectrometer 135 can be provided in order to determine the partial pressures of individual components of the residual gas.

Evaporation sources or effusion cells 100, 105, 110 and 115 are arranged opposite the surface of the substrate 230 that is to be coated. The number of effusion cells present is not restricted to the number illustrated. Rather, in individual embodiments of the invention, a larger or a smaller number of effusion cells or evaporation sources 100, 105, 110 and 115 can be provided.

The construction of an individual evaporation source 100, 105, 110 or 115 is known. An evaporation source generally comprises a reservoir of the material which is intended to form the molecular beam, that is to say, for example, aluminum, indium, gallium, antimony, arsenic or phosphorus. Said material can be heated by means of a heating device, whereupon individual atoms or molecules from the reservoir evaporate in the direction of the substrate 230. In order to influence the beam intensity, it is possible, for example, to alter the heating energy supplied or to provide a diaphragm at the exit opening. In order to measure the intensity of the emitted molecular beam of an evaporation source, it is possible to use an ionization manometer 140, for example, which can be brought into the beam of the evaporation sources 100, 105, 110 and 115 instead of the substrate 230 by rotation of the manipulator 150.

Optionally, further devices 120 for treating or coating the surface of the substrate 230 can be provided, for example a plasma generator, a sputtering source or the like.

For simultaneously interrupting the molecular beam of all the evaporation sources 100, 105, 110 and 115, it is possible to use a diaphragm 220, for example. Said diaphragm can be embodied as an iris diaphragm, for example, or be moved in between the exit openings of the evaporation sources 100, 105, 110 and 115 and the surface of the substrate 230 by means of a rotation or a translation in a manner known per se. In this way, the molecular beams impinge on the diaphragm 220, without reaching the surface of the substrate 230.

In the example illustrated, the vacuum chamber 200 is connected to a second vacuum chamber 300 by means of a slide 210. In this case, the slide 210 enables a largely gas-tight seal between the vacuum chambers 200 and 300. The substrate 230 can be transferred between the two vacuum chambers by a transfer rod 240 (illustrated by way of example) if the slide 210 is open. The vacuum chamber 300 can likewise have one or more vacuum pumps in order to produce a background pressure of less than 5·10⁻⁹ mbar or less than 5·10⁻¹⁰ mbar. During an interruption of growth, the substrate 230 can thus be positioned behind the closed slide 210 in the vacuum chamber 300 in order to interrupt the molecular beam from the evaporation sources 100, 105, 110 and 115. In this way, in a particularly simple manner, it was possible to set at least one of the evaporation sources and/or to determine the flow thereof by means of the ionization manometer 140.

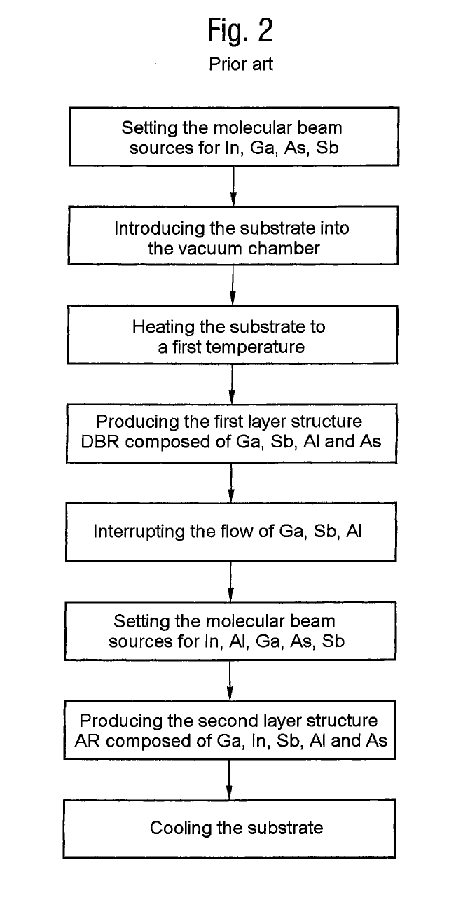

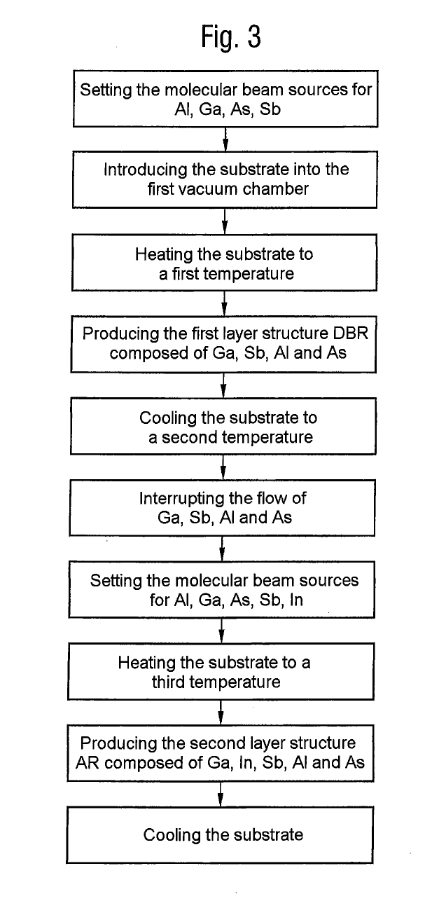

FIGS. 2 and 3 show manufacturing methods for a semiconductor laser. In this case, the semiconductor laser illustrated contains a semiconductor heterostructure composed of approximately 300 individual layers having a total thickness of approximately 9 μm.

In this case, the semiconductor heterostructure is again subdivided into a plurality of functional regions, the manufacture of, two functional regions being explained below. This concerns the active region AR of the semiconductor laser, which contains a multiplicity of individual layers composed of Ga_{0.76}In_{0.24}Sb and Al_{0.3}Ga_{0.7}As_{0.03}Sb_{0.97}. In this case, the individual layers can be produced continuously on the substrate by adaptation of the intensity of the molecular beams from 5 evaporation sources, which provide indium, aluminum, gallium, arsenic and antimony, by means of movable diaphragms.

Furthermore, the manufacture of a Bragg reflector DBR is illustrated. In this case, the Bragg reflector DBR consists of a multiplicity of individual layers containing GaSb and AlAs_{0.08}Sb_{0.92}. In this case, the individual layers are produced continuously on the substrate by adaptation of the intensity of the molecular beams from four evaporation sources, which provide aluminum, gallium, arsenic and antimony, by means of movable diaphragms.

FIG. 2 explains the previously known method. In this case, firstly the evaporation sources 100, 105, 110 and 115 are set. This comprises setting the temperature, the diaphragm position and measuring the emerging flow.

In the next method step, the substrate, for example monocrystalline GaSb, is introduced into the vacuum chamber 200 and brought to the required temperature, for example approximately 400° C. to approximately 700° C.

Afterward, firstly the layers of the Bragg reflector DBR are deposited continuously, wherein the changed chemical composition of the individual layers is achieved by means of a changed composition of the molecular beams. This is done by cyclically switching the movable diaphragms at the exit of the associated evaporation sources 100, 105, 110 and 115. After the Bragg reflector DBR has been completely produced, the last layer A forms the surface of the substrate 230.

In the known method, the growth of the individual layers is then interrupted in order to set the evaporation sources involved for producing the laser structure AR. In this case, this setting operation comprises, for example, setting a temperature of the source material, determining at least one diaphragm position and/or measuring the flow emerging from one of the evaporation sources.

In order to prevent the outgassing of constituents of the semiconductor heterostructure, for example the outgassing of arsenic, during this interruption of growth, a flow of arsenic and/or antimony onto the surface A of the substrate 230 is maintained during the duration of the interruption of growth. However, this flow leads to an undesirable transport of impurity atoms onto the surface of the substrate 230, such that an undesirable further layer containing InAsSb is formed on the surface A of the last deposited layer.

After the evaporation sources have been set for producing the laser material AR, the layers are produced by cyclically driving the diaphragms at the exit openings of the corresponding evaporation sources. Afterward, further layers can be produced or the substrate can be cooled and processed further within or outside the vacuum chamber 200.

FIG. 3 explains manufacturing method according to the invention for a nominally identical semiconductor laser. The first step involves setting the evaporation sources 100, 105, 110 and 115 for arsenic, gallium, aluminum and antimony. This comprises setting the temperature, the diaphragm position and measuring the emerging flow.

In the next method step, the substrate, for example monocrystalline GaSb, is introduced into the first vacuum chamber 200. At the same time or afterward, the substrate 230 is brought to the required temperature, for example approximately 400° C. to approximately 700° C.

Afterward, firstly the layers of the Bragg reflector DBR are deposited continuously, the changed chemical composition of the individual layers being achieved by means of a changed composition of the molecular beams. This is done by cyclically switching the movable diaphragms at the exit of the associated evaporation sources 100, 105, 110 and 115. For this purpose, the evaporation source which provides an indium beam can be switched off or at least ramped down, since the layer structure of the Bragg reflector DBR nominally contains no indium and, according to the invention, a longer time is available for the renewed setting of the evaporation sources. After the Bragg reflector DBR has been completely produced, the last layer A forms the termination of the Bragg reflector and at the same time temporarily also the surface of the substrate 230.

In accordance with the method according to the invention, the temperature of the substrate 230 is then reduced to an extent such than the individual elements of the semiconductor heterostructure do not evaporate in an appreciable amount from the surface A of the substrate 230. In this case, the temperature can be chosen in a manner dependent on the duration of the interruption of growth and/or in a manner dependent on the composition of the layer structure or the surface thereof.

Afterward, all the molecular beams can be switched off, including the molecular beams containing elements of main group V such as arsenic and antimony. This is preferably done by the substrate 230 being transferred from the first vacuum chamber 200 into the second vacuum chamber 300 and the connecting slide 210 being closed. In some cases, closing the diaphragm 230 can also suffice.

In the first vacuum chamber 200, the evaporation sources 100, 105, 110 and 115 can then be set anew, without the surface of the substrate 230 being adversely influenced. In one embodiment of the invention, the evaporation source which provides an indium beam can then be activated. In some cases, the beam intensities or fluxes emitted by the evaporation sources can be measured and set to a predeterminable desired value.

After this setting has been effected, the slide 210 is opened and the substrate 230 is transferred back from the second vacuum chamber 300 into the first vacuum chamber 200. The substrate 230 is thereupon brought to a third temperature, which can lie between 400° C. and 700° C., for example. In some cases, the third temperature can also be identical to the first temperature. At the same time, the flow of molecular beams that stabilizes the surface A is resumed and the layer structure of the laser material AR is subsequently produced by cyclically driving the diaphragms.

Afterward, further layers can be produced or the substrate can be cooled and processed further within or outside the vacuum chamber 200.

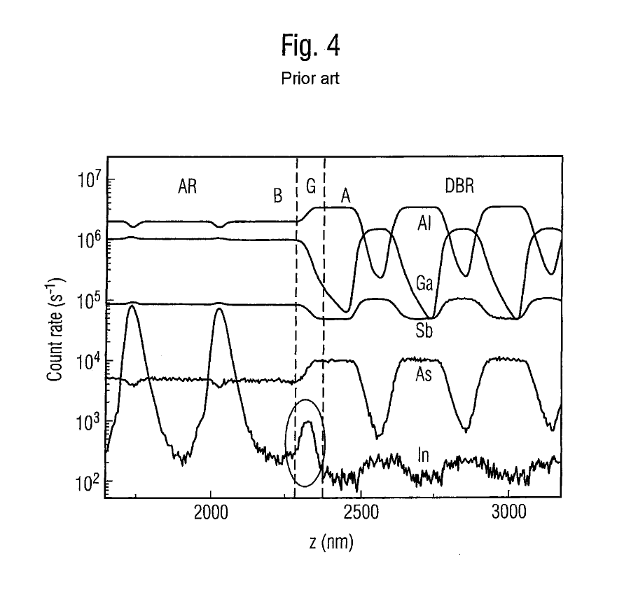

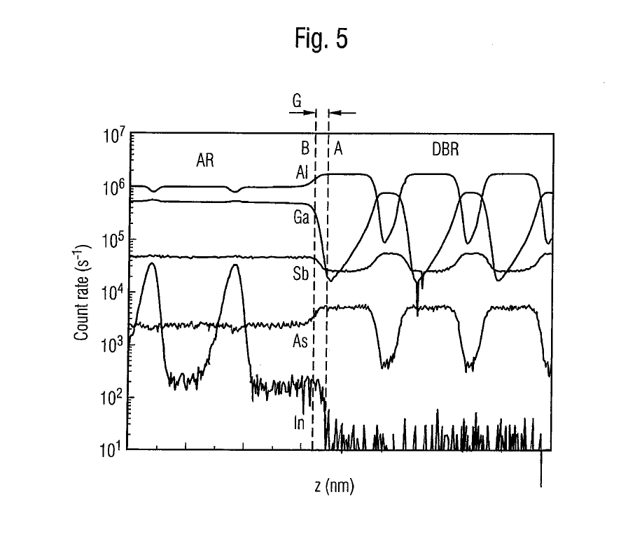

FIGS. 4 and 5 illustrate investigations by means of secondary ion mass spectrometry. For this purpose, the semiconductor heterostructure is irradiated with a low-energy ion beam, for example cesium ions of approximately 2 keV to approximately 15 keV. The constituents of the semiconductor heterostructure that are emitted under the ion bombardment can then be detected in a mass spectrometer. Since the semiconductor heterostructure is continuously resolved under increasing ion bombardment, depth profiles of the semiconductor heterostructure investigated can be recorded over the time duration of the bombardment.

FIG. 4 shows an excerpt from the depth-resolved element distribution of the layer structure of a semiconductor laser produced in accordance with the known manufacturing method.

FIG. 4 illustrates, at the left-hand edge of the figure, an excerpt from the active region AR of the semiconductor laser, containing a multiplicity of individual layers composed of Ga_{0.76}In_{0.24}Sb and Al_{0.3}Ga_{0.7}As_{0.03}Sb_{0.97}.

The right-hand part of the figure illustrates an excerpt from the layer structure of a Bragg reflector DBR. In this case, the Bragg reflector DBR consists of a multiplicity of individual layers containing GaSb and AlAs_{0.08}Sb_{0.92}. As can be seen from FIG. 4, however, the Bragg structure also contains indium as impurity, as a result of which the crystallinity of the layers and the performance of the Bragg reflector are reduced.

A boundary layer G forms between the Bragg reflector DBR and the active laser material AR. Said boundary layer contains InAsSb and thus reduces the performance of the laser material AR and/or the performance of the Bragg reflector.

In this case, the boundary layer G arises as a result of the flow of As and/or Sb which stabilizes the surface A and which transports impurities onto the surface A, such that they can deposit there. The contamination with indium can arise as a result of a slide that does not effect complete sealing or a non-sealing diaphragm at the exit of the corresponding evaporation source.

FIG. 5 shows an excerpt, identical to FIG. 4, from the depth-resolved element distribution of the layer structure of a semiconductor laser produced in accordance with the manufacturing method according to the invention.

It can now be seen from FIG. 5 that the boundary layer G between the last layer A of the Bragg reflector DBR and the first layer B of the laser material AR contains no contamination with indium. Consequently, an interface G containing InAsSb does not form either. As a result, the mechanical stress in the semiconductor heterostructure is reduced and/or the optical properties are improved.

Furthermore, according to the invention, a longer time is available for the renewed setting of the evaporation sources between the deposition of the Bragg reflector DBR and of the laser material AR. Consequently, the evaporation source which provides an indium beam can be switched off or ramped down into a standby state. As a result, the contamination of the Bragg reflector DBR with indium is reduced.

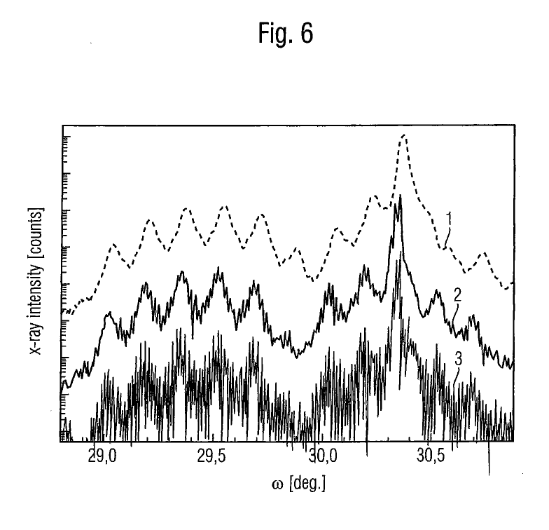

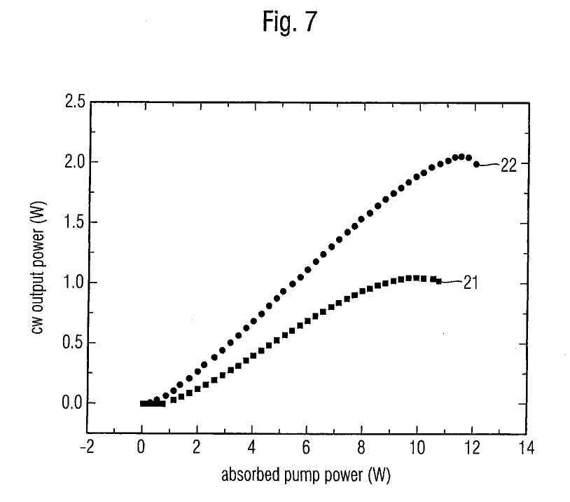

FIGS. 6 and 7 show the improved performance of the semiconductor laser manufactured according to the method according to the invention. In this case, FIG. 6 illustrates the result and the simulation of an X-ray structure analysis in the form of an X-ray intensity against the scattering angle. Curve 1 in FIG. 6 shows the measurements on a known semiconductor heterostructure. Curve 2 shows a measurement on a semiconductor heterostructure manufactured according to the invention. Curve 3 shows a theoretical calculation of the curve profile for the semiconductor heterostructure used. Consequently, curve 3 represents an optimum result that is theoretically achievable. In the comparison of the curve profiles it is noticeable that the maximum at 30.35° is widened in curve 1. This means that the coherently scattering regions in the known semiconductor heterostructure are smaller than in the case of the heterostructure manufactured according to the invention. Consequently, the number of lattice defects is smaller, such that the long-range order of the crystal lattice can be improved and the strain can be reduced.

Furthermore, the X-ray structure analysis shows between 29.0 and 30.0° five periodic maxima produced by the superlattice of the heterostructure. Only curve profiles 2 and 3 reveal, however, that a further periodic structure is superimposed on said superlattice. This means that the layer boundaries and hence the electronic structure of the semiconductor heterojunctions are more sharply distinct in the heterostructure manufactured according to the invention.

FIG. 7 shows the output power of a semiconductor laser against the pump power absorbed by the semiconductor crystal. In this case, curve profile 21 represents a known semiconductor laser. Curve profile 22 was measured with a semiconductor laser that was nominally identical but manufactured by the method according to the invention. For the measurements, the semiconductor heterostructure was optically pumped by means of a laser and the output power was measured. In this case, the semiconductor laser manufactured according to the invention exhibits an output power doubled in magnitude for an identical pump power by comparison with the known semiconductor laser. Furthermore, the maximum absorbed pump power can be increased by approximately 10%. The efficiency in the linear operating range, that is to say between approximately 2 W and approximately 9 W or 10 W of absorbed pump power, rises from approximately 14% in the case of the known semiconductor laser to approximately 22% for the semiconductor laser proposed according to the invention.

The invention has been described in detail on the basis of an exemplary embodiment. However, it should be pointed out that the invention is not restricted to the exemplary embodiment illustrated. Rather, the subject matter of the invention can undergo modifications and changes without departing from the central concept of the present invention. Therefore, the present description should not be regarded as restrictive, but rather as explanatory. In this case, the wording “contains”/“containing” in the claims does not preclude the fact that further features can be present in some embodiments of the invention. Furthermore, the indefinite article “a” or “an” does not constitute any exclusion of a plurality of elements.

1. A method for manufacturing semiconductor heterostructures by means of molecular beam epitaxy, comprising the following steps:
introducing a substrate into a first vacuum chamber,
heating the substrate to a first temperature,
providing at least one molecular beam from an evaporation source, said molecular beam comprising at least one element of main group V,
providing at least one molecular beam comprising at least one element of main group III,
producing a first epitaxial layer by deposition from the molecular beams, wherein the layer comprises a first material comprising a binary, ternary or quaternary compound of elements of main group III and V,
cooling the substrate to a second temperature, wherein at least the molecular beam of elements of main group III and V is interrupted,
heating the substrate to a third temperature,
producing a second epitaxial layer by deposition from at least one molecular beam, wherein the layer comprises a second material comprising a binary, ternary or quaternary compound of elements of main group III and V.

2. The method as claimed in claim 1, wherein the molecular beam is interrupted by the substrate being transferred into a second vacuum chamber.

3. The method as claimed in claim 1, wherein the molecular beam is interrupted by a diaphragm being arranged between the substrate and the source of the molecular beam.

4. The method as claimed in claim 1, wherein the first and third temperatures are greater than the second temperature.

5. The method as claimed in claim 1, wherein the emitted particle flux and/or the temperature of at least one evaporation source are/is changed and/or measured during the duration of the interruption of the molecular beam.

6. The method as claimed in claim 2, wherein a background pressure of less than 5·10⁻⁹ mbar prevails in the first and/or the second vacuum chamber.

7. The method as claimed in claim 1, wherein the elements of main group III are selected from aluminum, indium, gallium and the elements of main group V are selected from antimony, arsenic, and phosphorus.

8. The method as claimed in claim 1, wherein at least one additional layer is deposited which comprises any of a binary, ternary or quaternary compound of elements of main group III and V, without the molecular beam of elements of main group III and V being interrupted in between.

9. The method as claimed in claim 8, wherein approximately 50 to approximately 300 layers are produced.

10. The method as claimed in claim 1, wherein at least a part of any of a semiconductor laser or a photodetector is produced on the substrate.

11. An optoelectronic semiconductor component comprising a plurality of layers, wherein at least two of the layers are obtained by
introducing a substrate into a vacuum chamber,
bringing the substrate to a first temperature,
depositing a first epitaxial layer, wherein the layer contains a first material containing a binary, ternary, quaternary compound of elements of main group III and Antimony,
bringing the substrate to a second temperature, which is lower than the first temperature, wherein the molecular beam of elements of main group III and Antimony is interrupted,
bringing the substrate a third temperature, and
depositing a second epitaxial layer, wherein the second layer contains a second material containing a binary, ternary or quaternary compound of elements of main group III and Antimony.

12. The semiconductor component as claimed in claim 11, wherein the layers deposited on the substrate comprise any of aluminum, indium, and gallium.

13. The semiconductor component as claimed in claim 11, wherein a concentration of less than 0.2 at-% indium is present at the interface between the first layer and the second layer.

14. The semiconductor component as claimed in claim 11, comprising approximately 50 to approximately 1000 layers.

15. The semiconductor component as claimed in claim 14, comprising approximately 300 to approximately 900 layers.

16. The semiconductor component as claimed in claim 15, wherein the first layer is part of a light-reflecting structure and the second layer is part of a light-emitting or -absorbing active medium.

17. The semiconductor component as claimed in claim 16, comprising a quantum cascade laser and/or a quantum cascade detector.

18. A method for manufacturing semiconductor heterostructures by means of molecular beam epitaxy, comprising the following steps:
introducing a substrate into a first vacuum chamber,
heating the substrate to a first temperature,
providing at least one molecular beam from an evaporation source, said molecular beam comprising at least one element of main group V,
providing at least one molecular beam comprising at least one element of main group III,
producing a first epitaxial layer by deposition from the molecular beams, wherein the layer comprises a first material comprising a binary, ternary or quaternary compound of elements of main group III and V,
cooling the substrate to a second temperature, wherein at least the molecular beam of elements of main group III and V is interrupted,
adjusting and/or measuring the emitted particle flux and/or the temperature of at least one evaporation source,
heating the substrate to a third temperature,
producing a second epitaxial layer by deposition from at least one molecular beam, wherein the layer comprises a second material comprising a binary, ternary or quaternary compound of elements of main group III and V.

19. The method as claimed in claim 18, wherein the molecular beam is interrupted by the substrate being transferred into a second vacuum chamber.

20. The method as claimed in claim 18, wherein the molecular beam is interrupted by a diaphragm being arranged between the substrate and the source of the molecular beam.

21. The method as claimed in claim 18, wherein the first and third temperatures are greater than the second temperature.
